(19) United States
(12) Patent Application Publication
(10) Pub. No.: US 2024/0304530 A1
(43) Pub. Date: Sep. 12, 2024

(54) POWER CONVERTER APPARATUS

(71) Applicant: FUJI ELECTRIC CO., LTD., Kawasaki-shi (JP)

(72) Inventor: Hisato INOKUCHI, Matsumoto-city (JP)

(73) Assignee: FUJI ELECTRIC CO., LTD., Kawasaki-shi (JP)

(21) Appl. No.: 18/425,703

(22) Filed: Jan. 29, 2024

(30) Foreign Application Priority Data
Mar. 7, 2023 (JP) 2023-034416

(51) Int. Cl. H01L 23/495; H01L 23/00; H01L 23/373; H01L 25/065; H02M 7/00

(52) U.S. Cl. CPC H01L 23/49575; H01L 23/3735; H01L 23/4951; H01L 23/4952; H01L 24/08; H01L 24/48; H01L 25/0652; H02M 7/003; H01L 2224/08111; H01L 2224/08145; H01L 2224/48138; H01L 2224/48147; H01L 2924/01013; H01L 2924/01029; H01L 2924/13055; H01L 2924/13091

(57) ABSTRACT

A power converter apparatus includes a first wire connected to first and second conductive portions on a substrate. The first wire includes first and second bonding portions that are bonded respectively to the first and second conductive portions and each have at opposite ends thereof respectively a bonding end and a joining end; and a wiring portion having opposite ends, to which the joining ends of the first and second bonding portions are connected and being located away from the front surface of the substrate. In a plan view, a first extending direction in which the first bonding portion extends is inclined at a first acute angle, from a first direction of a first line passing through the bonding ends of first and second bonding portions, toward a second direction of a force that acts on the first bonding portion due to thermal expansion of the sealing member.

### CROSS-REFERENCE TO RELATED APPLICATION

This application is based upon and claims the benefit of priority of the prior Japanese Patent Application No. 2023-034416, filed on Mar. 7, 2023, the entire contents of which are incorporated herein by reference.

### BACKGROUND OF THE INVENTION

### 1. Field of the Invention

The embodiments discussed herein relate to a power converter apparatus.

### 2. Background of the Related Art

A power converter apparatus is configured with an insulated circuit board, on which semiconductor chips (or “power devices”) are disposed, housed inside a case. The insulated circuit board and semiconductor chips, wires used for wiring, and the like are sealed inside the case using a sealing member, such as silicone gel (see, for example, Japanese Laid-open Patent Publication No. 2022-77747). A semiconductor device in which a silicone resin sheet is disposed to suppress the deformation of wires when semiconductor elements are sealed has also been proposed (see, for example, Japanese Laid-open Patent Publication No. 2013-206925).

### SUMMARY OF THE INVENTION

According to an aspect, there is provided a power converter apparatus including: a substrate including a first conductive portion and a second conductive portion provided on a front surface thereof; a first wire that is connected to the first conductive portion and to the second conductive portion and includes: first and second bonding portions that are bonded respectively to the first and second conductive portions and each have at opposite ends thereof respectively a bonding end and a joining end; and a wiring portion having opposite ends, one of the opposite ends of the wiring portion being connected to the joining end of the first bonding portion and the other of the opposite ends of the wiring portion being connected to the joining end of the second bonding portion, the wiring portion being located away from the front surface of the substrate; a case including a housing region that houses the substrate and the first wire; and a sealing member that fills the housing region and seals the substrate and the first wire, wherein in a plan view of the power converter apparatus, a first extending direction in which the first bonding portion of the first wire extends from the bonding end of the first bonding portion to the first joining end of the first bonding portion is inclined at a first acute angle, from a first direction of a first line passing through the bonding ends of first and second bonding portions, toward a second direction of a force that acts on the first bonding portion due to thermal expansion of the sealing member.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a first plan view of a power converter apparatus according to a first embodiment;

FIG. 2 is a side view of the power converter apparatus according to the first embodiment;

FIG. 3 is a side cross-sectional view of the power converter apparatus according to the first embodiment;

FIG. 4 is a second plan view of the power converter apparatus according to the first embodiment;

FIG. 5 is a third plan view of the power converter apparatus according to the first embodiment;

FIG. 6 is a fourth plan view of the power converter apparatus according to the first embodiment;

FIG. 7 depicts an equivalent circuit for the functions of the power converter apparatus according to the first embodiment;

FIG. 8 depicts a direction of a force caused by thermal expansion of a sealing member and bonding directions of a wire;

FIG. 9 is a first enlarged view of a part of a power converter apparatus according to the first embodiment;

FIG. 10 depicts how a force changes according to a height of a covering member, and bonding directions of wires;

FIG. 11 is a second enlarged view of a part of the power converter apparatus according to the first embodiment; and

FIG. 12 depicts an erected (erect) state of wires in a power converter apparatus according to a second embodiment.

### DETAILED DESCRIPTION OF THE INVENTION

Several embodiments will be described below with reference to the accompanying drawings. Note that in the following description, the expressions “front surface” and “upper surface” refer to an X-Y plane that faces upward (that is, in the “+Z direction”) for the power converter apparatuses depicted in the drawings. In the same way, the expression “up” refers to the upward direction (or the “+Z direction”) for the power converter apparatuses depicted in the drawings. The expressions “rear surface” and “lower surface” refer to an X-Y plane that faces downward (that is, in the “−Z direction”) for the power converter apparatuses depicted in the drawings. In the same way, the expression “down” refers to the downward direction (or the “−Z direction”) for the power converter apparatuses depicted in the drawings. These expressions are used as needed to refer to the same directions in the other drawings. The expressions “front surface”, “upper surface”, “up”, “rear surface”, “lower surface”, “down”, and “side surface” are merely convenient expressions used to specify relative positional relationships, and are not intended to limit the technical scope of the present disclosure. As one example, “up” and “down” do not necessarily mean directions that are perpendicular to the ground. That is, the “up” and “down” directions are not limited to the direction of gravity. Additionally, in the following description, the expression “main component” refers to a component that composes 80% or higher by volume.

### First Embodiment

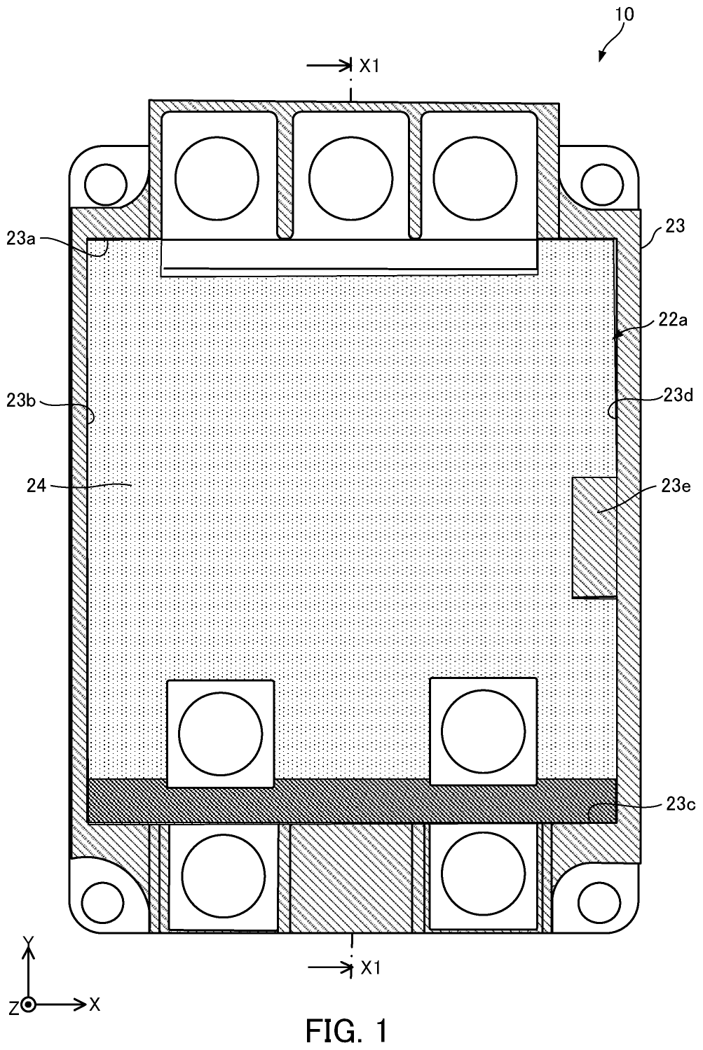

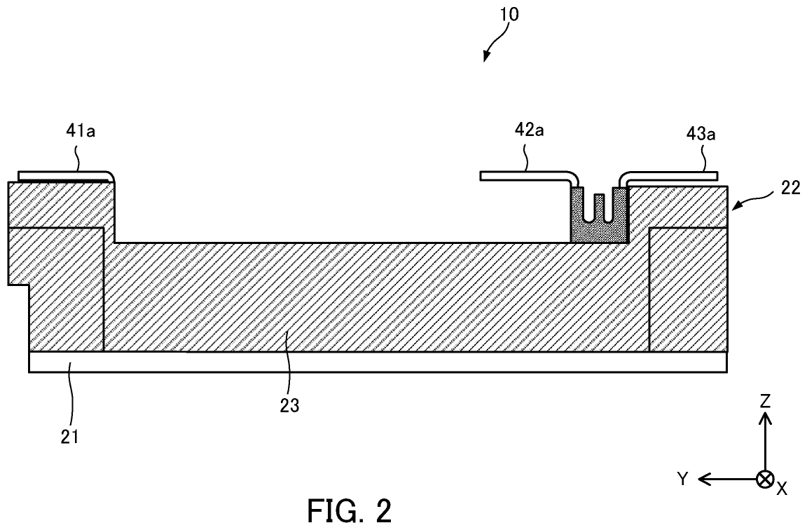

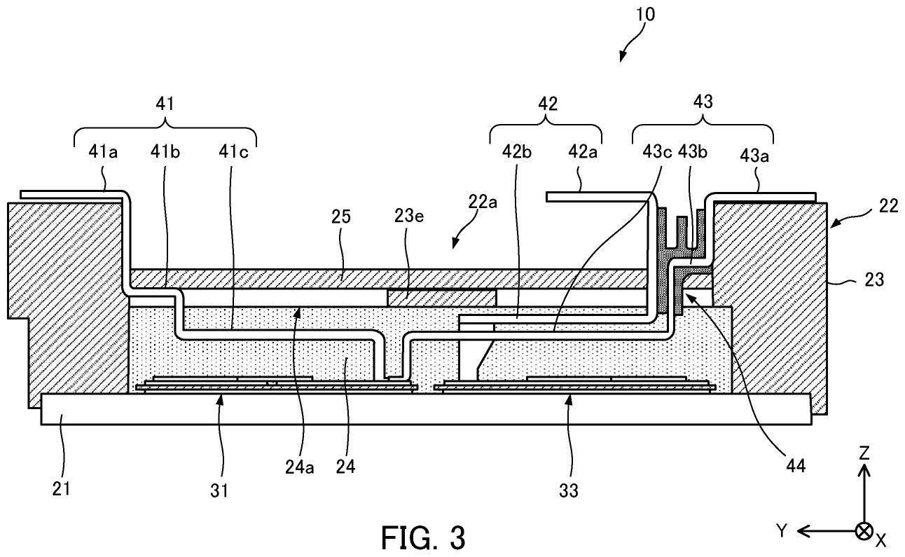

A power converter apparatus 10 according to the first embodiment will now be described with reference to FIGS. 1 to 3. FIG. 1 is a first plan view of a power converter apparatus according to the first embodiment. FIG. 2 is a side view of the power converter apparatus according to the first embodiment. FIG. 3 is a side cross-sectional view of the power converter apparatus according to the first embodiment. Note that FIG. 3 is a cross-sectional view taken along a chain line X1-X1 in FIG. 1. Note also that wires have been omitted from FIG. 3.

The power converter apparatus 10 includes a heat dissipating plate 21 disposed at the bottom, and a case 22 that is provided on the heat dissipating plate 21 and covers the sides of the power converter apparatus 10. The power converter apparatus 10 has components housed in a housing region 22a surrounded by the heat dissipating plate 21 and the case 22, and the components inside this housing region 22a are sealed with a sealing member 24. The housing region 22a is provided with components such as an insulated circuit board, semiconductor chips disposed on this insulated circuit board, wires that connect these components, and others. FIG. 3 depicts insulated circuit boards 31 and 33 as parts of the insulated circuit board. The power converter apparatus 10 is also provided with external connection terminals 41 to 43.

The heat dissipating plate 21 is a plate-like member that is substantially rectangular when viewed from above. The outer shape of the heat dissipating plate 21 may be slightly smaller than the outer shape of the case 22. Corner portions of the heat dissipating plate 21 may be chamfered into rounded or beveled shapes. The heat dissipating plate 21 is made of metal with superior heat dissipation. Examples of such metal are copper, aluminum, and an alloy containing at least one of copper and aluminum. A plating treatment may be performed to improve the corrosion resistance of the surface of the heat dissipating plate 21. When doing so, examples of the plating material used here are nickel, nickel-phosphorus alloy, and nickel-boron alloy.

An insulated circuit board is bonded to the front surface of the heat dissipating plate 21 via a bonding member such as solder. The insulated circuit board includes an insulating plate, circuit patterns formed on a front surface of the insulating plate, and a metal plate formed on a rear surface of the insulating plate. Note that the insulated circuit board will be described in detail later.

The insulating plate is rectangular in shape when viewed from above. Corner portions of the insulating plate may be chamfered into rounded or beveled shapes. The insulating plate is made of a ceramic that is highly thermally conductive. As examples, this ceramic is made of aluminum oxide, silicon nitride, or a material whose main component is aluminum nitride.

The circuit patterns are formed of a metal with superior electrical conductivity. Examples of such metal include copper, aluminum, and an alloy containing at least one of copper and aluminum. The surface of the circuit patterns may be plated to improve corrosion resistance. When doing so, examples of the plating material used here include nickel, nickel-phosphorus alloy, and nickel-boron alloy. Semiconductor chips and the external connection terminals 41 to 43 are mechanically and electrically connected as appropriate to the circuit patterns. Note that the structure of the circuit patterns and semiconductor chips will be described later.

The metal plate is formed of a metal with superior thermal conductivity as a main component. Examples of such a metal include copper, aluminum, and an alloy containing at least one of copper and aluminum. Plating may be performed to improve the corrosion resistance of the metal plate. Examples of the plating material used here are nickel, nickel-phosphorus alloy, and nickel-boron alloy.

As examples of an insulated circuit board with the components described above, it is possible to use a direct copper bonding (DCB) board or an active metal brazed (AMB) board. The circuit patterns on the insulated circuit board, and the semiconductor chips and the external connection terminals 41 to 43 are bonded together via solder. Lead-free solder is used as the solder. As examples, the lead-free solder has at least one alloy out of an alloy composed of tin-silver-copper, an alloy composed of tin-zinc-bismuth, an alloy composed of tin-copper, and an alloy composed of tin-silver-indium-bismuth as a main component. It is also possible to use sintered metal in place of the solder. A material of the sintered metal is silver, gold, nickel, copper, or an alloy containing at least one of these metals.

On the insulated circuit board on which the semiconductor chips have been mounted, wires are used to mechanically and electrically connect between the semiconductor chips, between the semiconductor chips and the circuit patterns, and between a plurality of circuit patterns. The wires are made of a material with superior electrical conductivity. Example materials include gold, silver, copper, aluminum, and an alloy containing at least one of these metals. When a wire is used at a control electrode of a semiconductor chip, as one example the diameter of the wire is 20 μm or more and 300 μm or less. Alternatively, when a wire is connected to the main electrode of a semiconductor chip and used as main current wiring, as one example the diameter of the wire is 350 μm or more and 500 μm or less.

The semiconductor chips may be made of silicon as a main component. Such semiconductor chips may include a reverse conducting-insulated gate bipolar transistor (RC-IGBT), which combines the functions of an IGBT and a free-wheeling diode (FWD). As one example, this type of semiconductor chip is provided with a collector electrode as an input electrode on the rear surface and a gate electrode as a control electrode and an emitter electrode as an output electrode on the front surface.

The present embodiment will be described using an example in which the semiconductor chips are RC-IGBTs. Note that the semiconductor chips may be configured using silicon carbide as a main component. As an example, the semiconductor chip may be a power metal-oxide-semiconductor field-effect transistor (power MOSFET). The semiconductor chips here include a power MOSFET and also an FWD. Each semiconductor chip of this type has a drain electrode as an input electrode on the rear surface, and a gate electrode as a control 5 electrode and a source electrode as an output electrode on the front surface. The semiconductor chips are each bonded via a bonding member to a predetermined circuit pattern on the insulated circuit board. The bonding member may be the solder described earlier or a sintered metal material. As examples, the sintered metal may have aluminum, copper, or an alloy containing at least one of aluminum and copper as a main component.

The case 22 includes a side wall portion 23 and a lid portion 25 that covers the upper portion of the housing region 22a. FIG. 1 is a plan view of a state where the lid portion 25 has been removed. The inner surfaces of the side wall portion 23 form a rectangle when viewed from above, and the side wall portion 23 includes first to fourth inner wall surfaces 23a to 23d that surround the housing region 22a on four sides. The first inner wall surface 23a and the third inner wall surface 23c correspond to short sides, and the second inner wall surface 23b and the fourth inner wall surface 23d correspond to long sides. Lower surfaces of the side wall portion 23 are bonded to the outer edges of the heat dissipating plate 21 using adhesive or the like. A protruding portion 23e that protrudes leftward in FIG. 1 is provided at an upper portion of the fourth inner wall surface 23d. The lower surface of the protruding portion 23e forms a facing surface on a plane facing the bottom of the housing region 22a. Note that out of the protruding portion 23e, at least the entire lower surface is in contact with the sealing member 24. The lower surface of the protruding portion 23e may be at a lower position than the upper surface 24a of the sealing member 24.

The side wall portion 23 and the lid portion 25 of the case 22 are integrally molded from thermoplastic resin by insert molding so as to include the external connection terminals 41 to 43. Examples of such resin include polyphenylene sulfide resin, polybutylene terephthalate resin, polybutylene succinate resin, polyamide resin, and acrylonitrile butadiene styrene resin.

The housing region 22a surrounded by the heat dissipating plate 21 and the side wall portion 23 of the case 22 is filled with a sealing member 24. By doing so, the insulated circuit board and components such as the circuit patterns, the semiconductor chips, and the wires disposed in the housing region 22a are sealed by the sealing member 24. The sealing member is an electrically insulating polymer gel, and preferably has silicone gel as a main component.

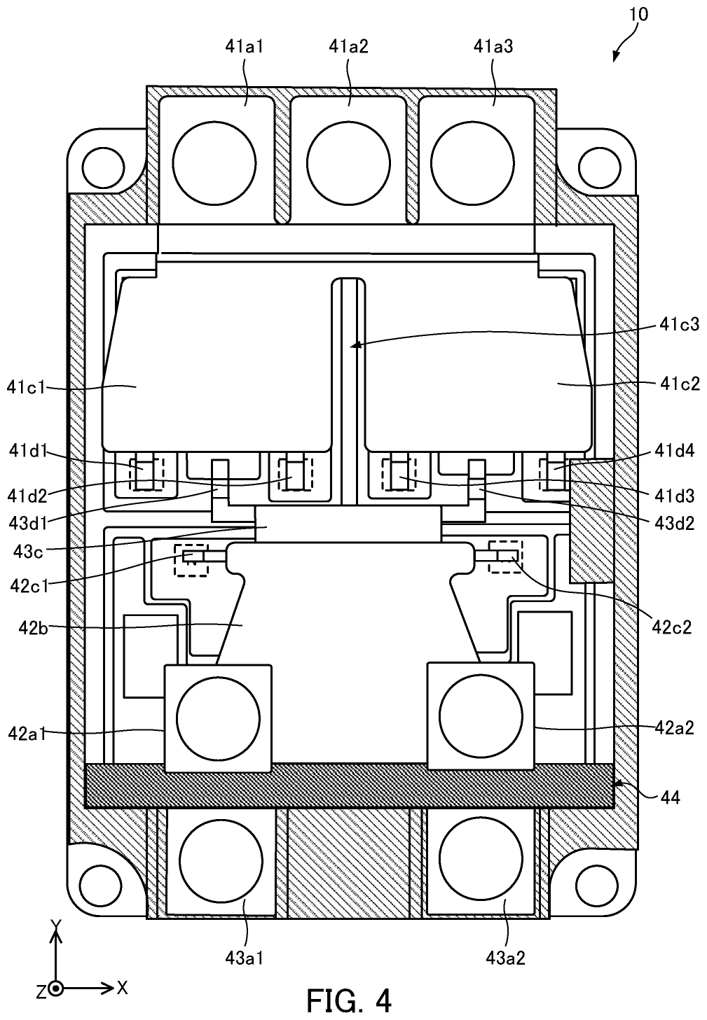

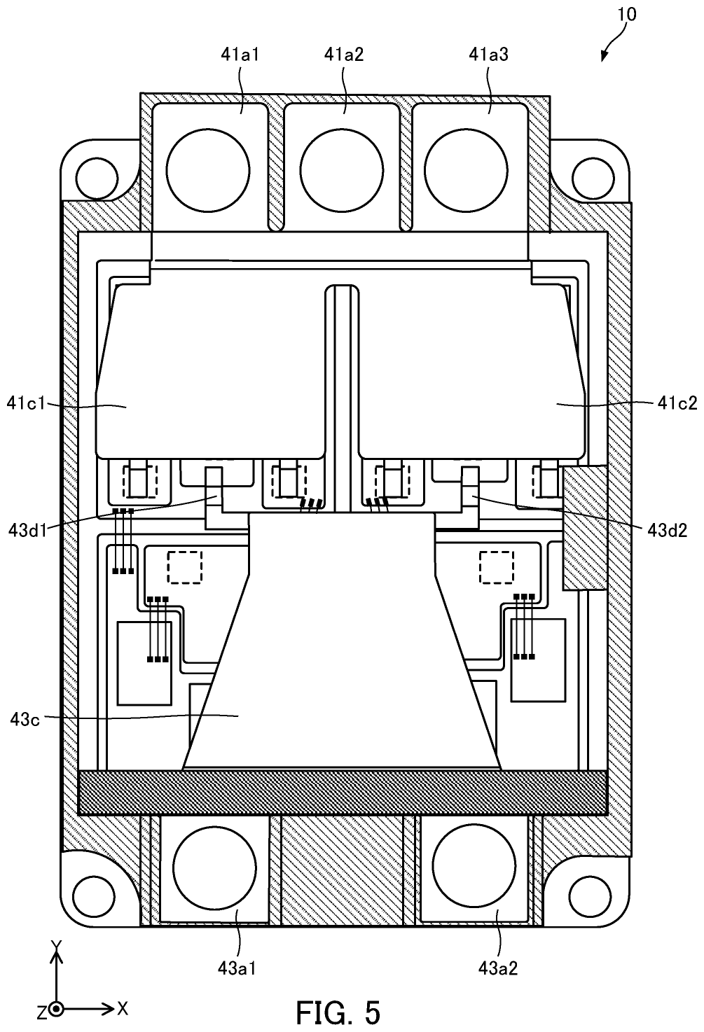

FIG. 4 is a second plan view of the power converter apparatus according to the first embodiment. FIG. 5 is a third plan view of the power converter apparatus according to the first embodiment. Note that FIG. 4 depicts a state where the sealing member 24 inside the housing region 22a of the case 22 has been removed from the first plan view in FIG. 1. Wires have also been omitted from FIG. 4. FIG. 5 depicts a state where the external connection terminal 42 has also been omitted from the second plan view in FIG. 4. The external connection terminals 41 to 43 will be described below with reference to FIGS. 3 to 5.

The external connection terminals 41 to 43 electrically connect the circuit patterns and external devices. The external connection terminals 41 to 43 are formed of conductive members in the form of flat plates. Note that parts of the external connection terminals 42 and 43 are integrally held by a terminal holding portion 44.

One end of the external connection terminal 41 is exposed from the upper surface of the lid portion 25 of the case 22 and forms an external connection portion 41a that is connected to an external device. The external connection terminal 41 also includes horizontal portions 41b and 41c disposed in that order from the external connection portion 41a to the other end side. The horizontal portions 41b and 41c are parallel to the bottom surface of the housing region 22a, with the height of the horizontal portion 41b lower than the external connection portion 41a and the height of the horizontal portion 41c lower than the horizontal portion 41b. As one example, the external connection portion 41a and the horizontal portions 41b and 41c are formed by bending the external connection terminal 41, which is in the form of a flat plate, and joining portions that extend in the vertical direction are formed to join the external connection portion 41a to the horizontal portion 41b and the horizontal portion 41b to the horizontal portion 41c.

The external connection portion 41a is divided into external connection portions 41a1 to 41a3 in the horizontal direction (the X direction). The horizontal portion 41c is divided into horizontal portions 41c1 and 41c2 in the horizontal direction (the X direction) with a central slit 41c3 that extends in between. In addition, connection portions 41d1 and 41d2 that extend downward are formed at an end portion of the horizontal portion 41c1. The connection portions 41d1 and 41d2 are electrically and mechanically connected via solder to circuit patterns 31b and 31c (described later), respectively. Connection portions 41d3 and 41d4 that extend downward are also formed at an end portion of the horizontal portion 41c2. The connection portions 41d3 and 41d4 are electrically and mechanically connected via solder to circuit patterns 32b and 32c (described later), respectively. As an alternative example, such parts may be directly connected by laser welding or ultrasonic welding.

One end of the external connection terminal 42 is exposed on the upper surface of the lid portion 25 of the case 22, and forms an external connection portion 42a that is connected to an external device. The external connection portion 42a is divided into external connection portions 42a1 and 42a2 in the horizontal direction (the X direction). The external connection terminal 42 also includes a horizontal portion 42b at the other end to the external connection portion 42a. The horizontal portion 42b is parallel to the bottom surface of the housing region 22a, and the height of the horizontal portion 42b is lower than the external connection portion 42a. The external connection portion 42a and the horizontal portion 42b are formed by bending the external connection terminal 42, which is in the form of a flat plate, so that the external connection portion 42a and the horizontal portion 42b are joined by a joining portion that extends in the vertical direction.

Connection portions 42c1 and 42c2 that extend downward are formed at an end portion of the horizontal portion 42b. The T connection portions 42c1 and 42c2 are electrically and mechanically connected via solder to circuit patterns 33b and 34b (described later), respectively. As an alternative example, such parts may be directly connected by laser welding or ultrasonic welding.

One end of the external connection terminal 43 is exposed from the upper surface of the lid portion 25 of the case 22, and forms the external connection portion 43a that is connected to an external device. The external connection terminal 43 also includes horizontal portions 43b and 43c in that order from the external connection portion 43a to the other end. The horizontal portions 43b and 43c are parallel to the bottom surface of the housing region 22a, the height of the horizontal portion 43b is lower than that of the external connection portion 43a, and the height of the horizontal portion 43c is lower than that of the horizontal portion 43b. The external connection portion 43a and the horizontal portions 43b and 43c are formed by bending the external connection terminal 43 which is in the form of a flat plate, with joining portions that both extend in the vertical direction joining the external connection portion 43a to the horizontal portion 43b and the horizontal portion 43b to the horizontal portion 43c.

The external connection portion 43a is divided in the horizontal direction (the X direction) into external connection portions 43a1 and 43a2. Connection portions 43d1 and 43d2 that extend downward are formed at an end portion of the horizontal portion 43c. The connection portions 43d1 and 43d2 are electrically and mechanically connected via solder to circuit patterns 31a and 32a (described later), respectively. As an alternative example, such parts may be directly connected by laser welding or ultrasonic welding.

The terminal holding portion 44 seals the joining portion that joins the external connection portion 42a and the horizontal portion 42b of the external connection terminal 42, the joining portion that joins the external connection portion 43a and the horizontal portions 43b and 43c of the external connection terminal 43, and the horizontal portion 43b. By doing so, electrical insulation is maintained even when the external connection terminals 42 and 43 are disposed close to each other. This terminal holding portion 44 may be made of the same material as the case 22.

Note that although not illustrated, one or more control terminals may also be provided. Each control terminal has one end exposed from the case 22 or from the lid portion 25 of the case 22, with the other end being disposed inside the housing region 22a. The other end of each control terminal is electrically connected to a control electrode of a semiconductor chip. The other end of the control terminal may be mechanically and electrically connected to the control electrode of a semiconductor chip by a control wire. The other end of the control terminal and the control wire may be connected via a circuit pattern. Note that the diameter of the control wire may be smaller than the diameter of a wire used as the main current wiring.

The horizontal portion 41c of the external connection terminal 41, the horizontal portion 42b of the external connection terminal 42, and the horizontal portion 43c of the external connection terminal 43 are disposed at lower positions than the upper surface 24a of the sealing member 24 and are therefore sealed by the sealing member 24.

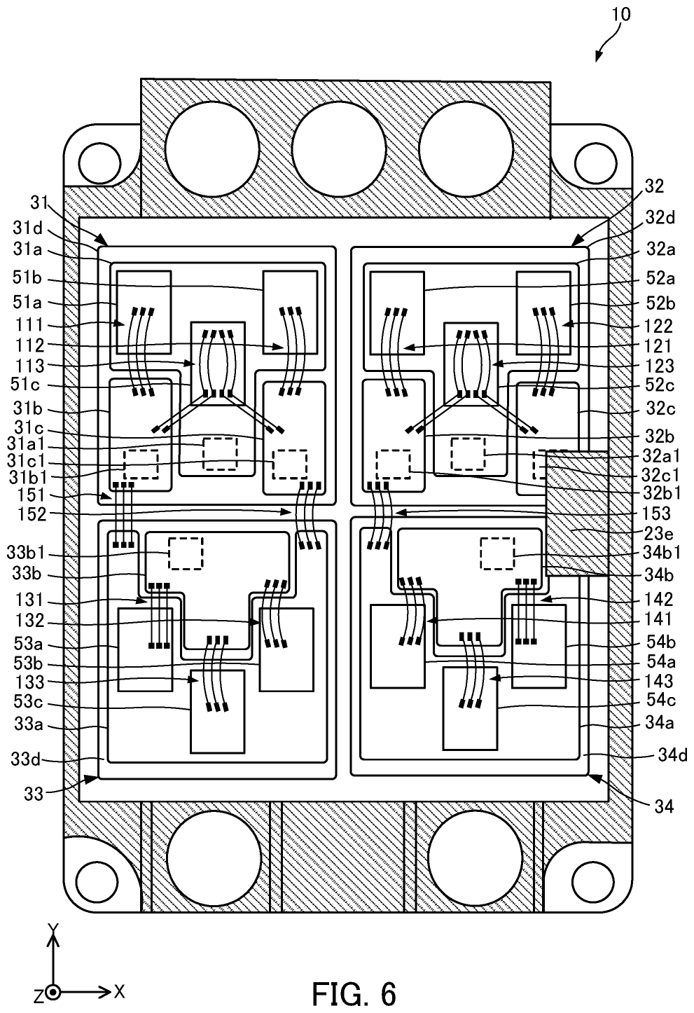

FIG. 6 is a fourth plan view of the power converter apparatus according to the first embodiment. Note that FIG. 6 depicts a state where the external connection terminals 41 and 43 have been removed from the third plan view in FIG. 5. The configurations of the insulated circuit board, the semiconductor chips, and the wires will be described below with reference to FIG. 6.

The insulated circuit boards 31 to 34 are bonded to the front surface of the heat dissipating plate 21. The circuit patterns 31a to 31c are formed on the front surface of an insulating plate 31d included in the insulated circuit board 31. The circuit patterns 32a to 32c are formed on the front surface of an insulating plate 32d included in the insulated circuit board 32. The circuit patterns 33a and 33b are formed on the front surface of an insulating plate 33d included in the insulated circuit board 33. The circuit patterns 34a and 34b are formed on the front surface of an insulating plate 34d included in the insulated circuit board 34.

The circuit pattern 31a is T-shaped when viewed from above. The circuit pattern 31a is provided close to a +Y direction end of the insulating plate 31d. Semiconductor chips 51a to 51c are disposed on the circuit pattern 31a. The semiconductor chips 51a and 51b are disposed on both sides in the ±X direction of the circuit pattern 31a. The semiconductor chip 51c is disposed in the center of the circuit pattern 31a between the semiconductor chips 51a and 51b. Rear surfaces of the semiconductor chips 51a to 51c and the circuit pattern 31a are mechanically and electrically bonded via solder as a bonding member.

The circuit patterns 31b and 31c are rectangular in shape when viewed from above. The circuit patterns 31b and 31c are disposed on the insulating plate 31d on both sides of a part of the circuit pattern 31a that protrudes in the −Y direction. Wires (first wires) 111 mechanically and electrically connect the output electrode on the front surface of the semiconductor chip 51a and the circuit pattern 31b. Wires 112 mechanically and electrically connect the output electrode on the front surface of the semiconductor chip 51b and the circuit pattern 31c. Wires 113 mechanically and electrically connect the output electrode on the front surface of the semiconductor chip 51c and the circuit patterns 31b and 31c.

Wires 151 mechanically and electrically connect the circuit pattern 31b and the circuit pattern 33a. Wires 152 mechanically and electrically connect the circuit pattern 31c and the circuit pattern 33a.

The connection portion 43d1 of the external connection terminal 43 is electrically and mechanically connected via solder to a region 31a1 of the circuit pattern 31a. The connection portion 41d1 of the external connection terminal 41 is electrically and mechanically connected via solder to a region 31b1 of the circuit pattern 31b. The connection portion 41d2 of the external connection terminal 41 is electrically and mechanically connected via solder to a region 31c1 of the circuit pattern 31c.

The circuit pattern 32a is T-shaped when viewed from above. The circuit pattern 32a is provided close to a +Y direction end of the insulating plate 32d. Semiconductor chips 52a to 52c are disposed on the circuit pattern 32a. The semiconductor chips 52a and 52b are disposed on both sides in the ±X direction of the circuit pattern 32a. The semiconductor chip 52c is disposed in the center of the circuit pattern 32a between the semiconductor chips 52a and 52b. Rear surfaces of the semiconductor chips 52a to 52c and the circuit pattern 32a are mechanically and electrically bonded via solder as a bonding member.

The circuit patterns 32b and 32c are rectangular in shape when viewed from above. The circuit patterns 32b and 32c are disposed on the insulating plate 32d on both sides of a part of the circuit pattern 32a that protrudes in the −Y direction. Wires 121 mechanically and electrically connect the output electrode on the front surface of the semiconductor chip 52a and the circuit pattern 32b. Wires 122 mechanically and electrically connect the output electrode on the front surface of the semiconductor chip 52b and the circuit pattern 32c. Wires 123 mechanically and electrically connect the output electrode on the front surface of the semiconductor chip 52c and the circuit patterns 32b and 32c.

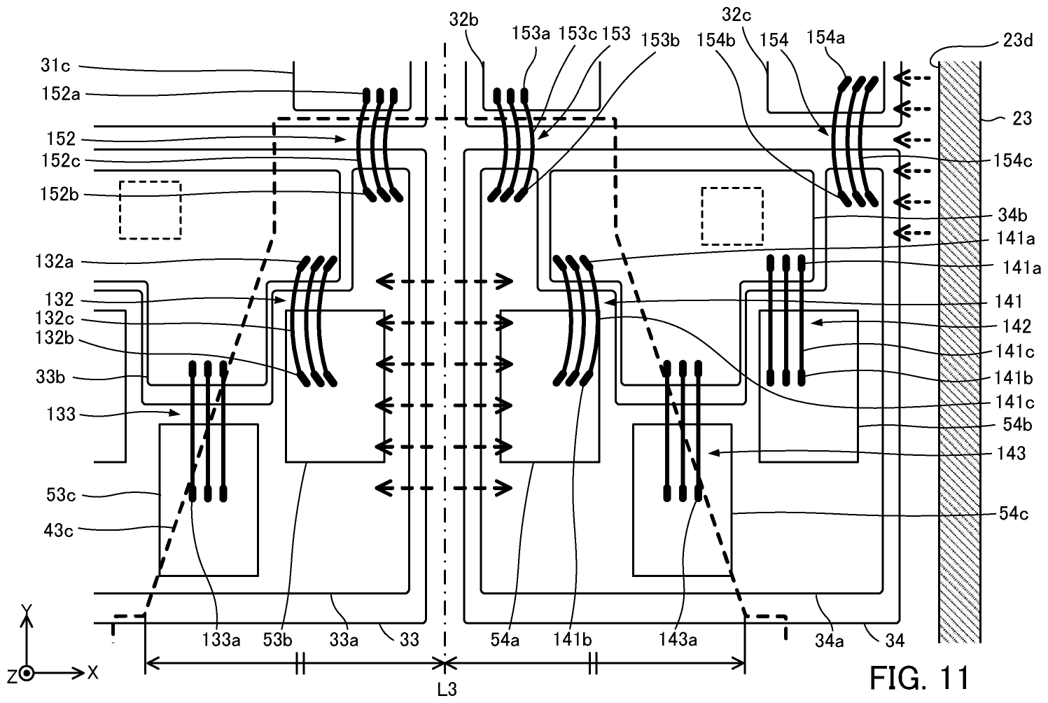

Wires 153 mechanically and electrically connect the circuit pattern 32b and the circuit pattern 34a. Wires 154 mechanically and electrically connect the circuit pattern 32c and the circuit pattern 34a. Note that the wires 154 are illustrated in FIG. 11.

The connection portion 43d2 of the external connection terminal 43 is electrically and mechanically connected by solder to a region 32a1 of the circuit pattern 32a. The connection portion 41d3 of the external connection terminal 41 is electrically and mechanically connected by solder to a region 32b1 of the circuit pattern 32b. The connection portion 41d4 of the external connection terminal 41 is electrically and mechanically connected by solder to the region 32c1 of the circuit pattern 32c.

The circuit pattern 33a is U-shaped when viewed from above. The circuit pattern 33a is provided close to a −Y direction end of the insulating plate 33d. Semiconductor chips 53a to 53c are disposed on the circuit pattern 33a. The semiconductor chips 53a and 53b are disposed on both sides of a recess in the circuit pattern 33a. The semiconductor chip 53c is disposed between the semiconductor chips 53a and 53b in the center of the −Y direction end of the circuit pattern 33a. Rear surfaces of the semiconductor chips 53a to 53c and the circuit pattern 33a are mechanically and electrically bonded via solder as a bonding member.

The circuit pattern 33b is T-shaped when viewed from above and is formed inside the recess of the circuit pattern 33a close to the +Y direction end of the insulating plate 33d. Wires 131 mechanically and electrically connect the output electrode on the front surface of the semiconductor chip 53a and the circuit pattern 33b. Wires 132 mechanically and electrically connect the output electrode on the front surface of the semiconductor chip 53b and the circuit pattern 33b. Wires 133 mechanically and electrically connect the output electrode on the front surface of the semiconductor chip 53c and the circuit pattern 33b.

The circuit pattern 34a is U-shaped when viewed from above. The circuit pattern 34a is provided close to the −Y direction end of the insulating plate 34d. Semiconductor chips 54a to 54c are disposed on the circuit pattern 34a. The semiconductor chips 54a and 54b are disposed on both sides of a recess in the circuit pattern 34a. The semiconductor chip 54c is disposed between the semiconductor chips 54a and 54b in the center of the −Y direction end of the circuit pattern 34a. Rear surfaces of the semiconductor chips 54a to 54c and the circuit pattern 34a are mechanically and electrically connected by solder.

The circuit pattern 34b is T-shaped when viewed from above and is formed inside the recess of the circuit pattern 34a close to the +Y direction end of the insulating plate 34d. Wires 141 mechanically and electrically connect the output electrode on the front surface of the semiconductor chip 54a and the circuit pattern 34b. Wires 142 mechanically and electrically connect the output electrode on the front surface of the semiconductor chip 54b and the circuit pattern 34b. Wires 143 mechanically and electrically connect the output electrode on the front surface of the semiconductor chip 54c and the circuit pattern 34b.

A connection portion 42c1 of the external connection terminal 42 is electrically and mechanically connected by solder to a region 33b1 of the circuit pattern 33b. A connection portion 42c2 of the external connection terminal 42 is electrically and mechanically connected by solder to a region 34b1 of the circuit pattern 34b.

The wires 111 to 113, 121 to 123, 131 to 133, 141 to 143, and 151 to 154 described above are bonding wires whose main component is a metal with superior electrical conductivity. Such metals include aluminum, copper, or an alloy containing at least one of aluminum and copper. In the present embodiment, the wires 111 to 113, 121 to 123, 131 to 133, 141 to 143, and 151 to 154 described above are used as main current wiring and as one example have diameters that are 300 μm or more and 500 μm or less.

Note that bonding of the wires 111 to 113, 121 to 123, 131 to 133, 141 to 143, and 151 to 154 to the conductive portions (that is, the circuit patterns or the output electrodes on the front surfaces of the semiconductor chips) may be performed using a bonding apparatus. A bonding tool included in the bonding apparatus applies ultrasonic vibration while pressing the wires 111 to 113, 121 to 123, 131 to 133, 141 to 143, and 151 to 154 against the conductive portions. By performing such wedge bonding, the wires 111 to 113, 121 to 123, 131 to 133, 141 to 143, and 151 to 154 are bonded to the conductive portions.

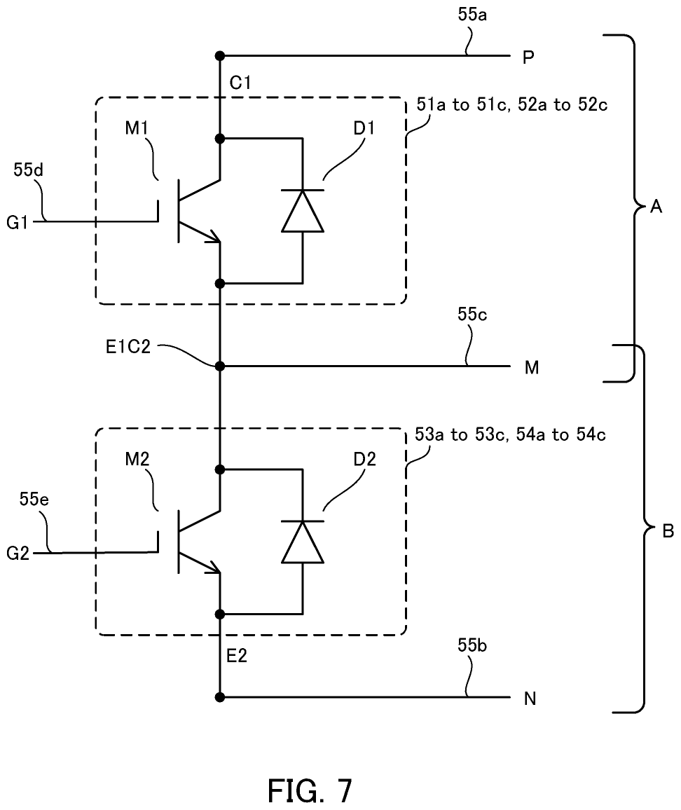

As described earlier, the semiconductor chips 51a to 51c, 52a to 52c, 53a to 53c, and 54a to 54c described above are RC-IGBTs in which the functions of an IGBT and an FWD are combined. The power converting function of the power converter apparatus 10 will now be described with reference to FIG. 7.

FIG. 7 depicts an equivalent circuit for the functions of the power converter apparatus according to the first embodiment. FIG. 7 depicts an inverter circuit formed of semiconductor chips 51a to 51c and 52a to 52c and semiconductor chips 53a to 53c and 54a to 54c, which include RC-IGBT. The semiconductor chips 51a to 51c and 52a to 52c each include a switching element (IGBT) M1 and a diode element (FWD) D1. The semiconductor chips 53a to 53c and 54a to 54c each include a switching element (IGBT) M2 and a diode element (FWD) D2.

The power converter apparatus 10 forms a half-bridge circuit including an upper arm A and a lower arm B. The upper arm A of the power converter apparatus 10 includes the wires 111 to 113 and the wires 121 to 123, the semiconductor chips 51a to 51c and the semiconductor chips 52a to 52c, and the external connection terminal 43 that are disposed on the insulated circuit board 31 and the insulated circuit board 32. In addition, the power converter apparatus 10 includes the external connection terminal 41 that is disposed on the circuit patterns 31b and 31c of the insulated circuit board 31 and the circuit patterns 32b and 32c of the insulated circuit board 32.

The lower arm B of the power converter apparatus 10 includes the wires 131 to 133 and the wires 141 to 143, the semiconductor chips 53a to 53c and the semiconductor chips 54a to 54c, and the external connection terminal 42 that are disposed on the insulated circuit board 33 and the insulated circuit board 34.

The insulated circuit board 31 and the insulated circuit board 33 are connected by the wires 151 and 152, and the insulated circuit board 32 and the insulated circuit board 34 are connected by the wires 153 and 154. By doing so, the upper arm A and the lower arm B are connected. With this configuration, the power converter apparatus 10 is operatable as a half-bridge circuit including the upper arm A and the lower arm B.

In this case, for the power converter apparatus 10, wiring 55a that connects a connection point P connected to the positive electrode of an external power source (not illustrated) and a connection point C1 with input electrodes (collector electrodes) on the rear surfaces of the semiconductor chips 51a to 51c and 52a to 52c corresponds to the external connection terminal 43 and the circuit patterns 31a and 32a. That is, the external connection terminal 43 is a P terminal that servers as a positive electrode-side input terminal of a half-bridge circuit.

Wiring 55c that connects a connection point M connected to a terminal of a load (not illustrated) and a connection point E1C2 between the output electrodes (emitter electrodes) of the semiconductor chips 51a to 51c and the semiconductor chips 52a to 52c and the input electrodes (collector electrodes) of the semiconductor chips 53a to 53c and the semiconductor chips 54a to 54c corresponds to the external connection terminal 41 and the circuit patterns 31b and 31c, the circuit patterns 32b and 32c, the wires 151 and 152, the wires 153 and 154, and the circuit patterns 33a and 34a. That is, the external connection terminal 41 is an M terminal that serves as an output terminal of the half-bridge circuit.

Wiring 55b that connects a connection point N that is connected to the negative electrode of the external power source and a connection point E2 between output electrodes (emitter electrodes) of the semiconductor chips 53a to 53c and 54a to 54c corresponds to the external connection terminal 42 and the circuit patterns 33b and 34b. In other words, the external connection terminal 42 is an N terminal that serves as a negative electrode-side input terminal of the half-bridge circuit.

Wiring 55d and 55e that connects a connection point G1 and a connection point G2, into which control signals are inputted, and the control electrodes (gate electrodes) of the semiconductor chips 51a to 51c and 52a to 52c and the semiconductor chips 53a to 53c and 54a to 54c correspond to control terminals, not illustrated.

As described earlier, the housing region 22a of the case 22 is filled with the sealing member 24. The semiconductor chips 51a to 51c, 52a to 52c, 53a to 53c, 54a to 54c and the wires 111 to 113, 121 to 123, 131 to 133, 141 to 143, and 151 to 154 described above are sealed by the sealing member 24.

When a semiconductor chip operates, heat is generated, with such heat causing the sealing member 24 in the periphery of the semiconductor chip to expand. As one example, when a covering member including a facing surface that faces the bottom surface of the housing region 22a is present above the sealing member 24 (in the Z direction), upward expansion of the sealing member 24 is suppressed and the sealing member 24 expands in horizontal directions (parallel to the X-Y plane). As a result, a force may be generated in the horizontal directions due to thermal expansion of the sealing member 24.

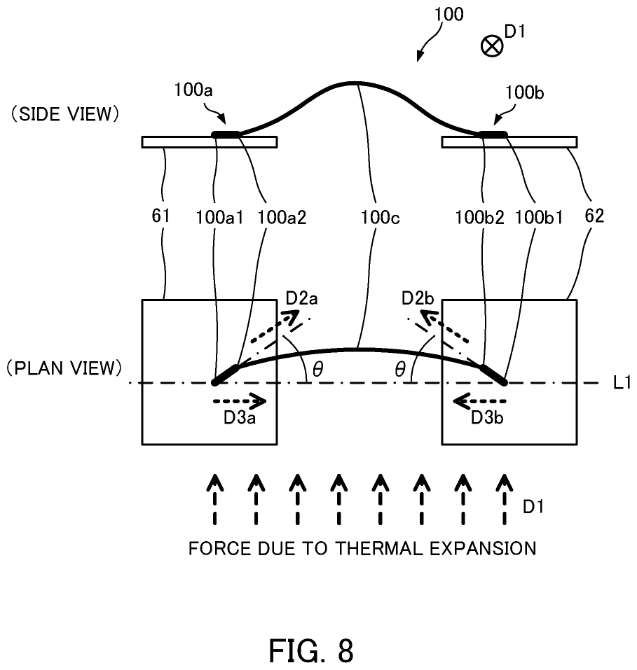

The wires that are subjected to a force due to thermal expansion of the sealing member 24 will be described below with reference to FIG. 8. FIG. 8 depicts the direction of a force caused by thermal expansion of the sealing member and the bonding directions of a wire. FIG. 8 depicts a wire 100 that connects a conductive portion 61 and a conductive portion 62. The upper part of FIG. 8 is a side view, and the lower part of FIG. 8 is a plan view. Note that the conductive portion 61 is a circuit pattern or an output electrode of a semiconductor chip. In the same way, the conductive portion 62 is a circuit pattern or an output electrode of a semiconductor chip. In this way, the conductive portions 61 and 62 are components to which wires are bonded, but are not limited to circuit patterns or output electrodes and for example may be electrodes of other electronic components, lead frames, or metal blocks.

The wire 100 includes bonding portions 100a and 100b and a wiring portion 100c. The bonding portion 100a is a part of the wire 100 that is pressed against and bonded to the conductive portion 61 by ultrasonic vibration using a bonding tool. This bonding portion 100a extends from one end (bonding end) 100a1 to a joining portion 100a2 of the wire 100, with the entire bonding portion 100a being bonded to the conductive portion 61. In the same way, the bonding portion 100b is a part of the wire 100 that is bonded to the conductive portion 62 using a bonding tool. This bonding portion 100b extends from the other end 100b1 to a joining portion 100b2 of the wire 100, with the entire bonding portion 100b being bonded to the conductive portion 62. The wiring portion 100c spans between the conductive portion 61 and the conductive portion 62 to connect the joining portion 100a2 of the bonding portion 100a and the joining portion 100b2 of the bonding portion 100b, and is upwardly separated (that is, upwardly separated in the side view of FIG. 8) from the front surface of the insulated circuit board on which the conductive portions 61 and 62 are disposed.

In FIG. 8, as one example, it is assumed that a force due to thermal expansion of the sealing member 24 is generated at a position indicated in the upper part of FIG. 8 so as to act in in a direction Dl perpendicular to a straight line L1 that connects the bonding portions 100a and 100b. When this force acts on the wire 100, the stress generated at the bonding portions 100a and 100b, which are the base parts of the wire 100, may cause the bonding portions 100a and 100b to become detached from (that is, lift off) the conductive portions 61 and 62. In particular, inside a case where stress is repeatedly generated, such as during a heat cycle test or a power cycle test, the risk of detachment of the wire 100 tends to increase.

Here, as a method of reducing the force that acts on the bonding portions 100a and 100b due to thermal expansion, it would be conceivable for example to dispose a partition member to restrict movement of the sealing member 24 that expands. As one example, in FIG. 8, a substantially flat partition member that is parallel to the straight line L1 could be disposed on the side of the conductive portions 61 and 62 where the force is generated (that is, below the conductive portions 61 and 62 in FIG. 8). As one example, this partition member could be formed so as to extend downward from the lid portion 25 of the case 22 to a position with a gap from the bottom of the housing region 22a. However, disposing this type of partition member in keeping with the positions of the semiconductor chips and wires causes a problem of increased development and manufacturing costs for the power converter apparatus 10. There is also a problem of restricted freedom in laying out circuit patterns, semiconductor chips, and wires, and in some cases, the power converter apparatus 10 as a whole will become larger.

For this reason, in the present embodiment, by inclining the directions in which the bonding portions 100a and 100b of the wire 100 are bonded toward the direction D1 of the force caused by thermal expansion of the sealing member 24, the risk of the wire 100 becoming detached is reduced. In more detail, the wire 100 is bonded so that the direction D2a (first extending direction) in which the bonding portion 100a extends from the one end (bonding end) 100a1 toward the joining end 100a2 of the bonding portion 100a is inclined at an angle θ (where θ>0), from a direction (first direction) D3a that joins the bonding portion 100a (bonding end 100a1 of the bonding portion 100a) to the bonding portion 100b (bonding end 100b1 of the bonding portion 100b). The wire 100 is also bonded so that the direction D2b in which the bonding portion 100b extends from the other end 100b1 toward the joining portion 100b2 is inclined by an angle θ (where θ>0) with respect to a direction D3b that joins the bonding portion 100b to the bonding portion 100a. In this connection, when the direction D1 of the force is perpendicular to the directions D3a and D3b as depicted in FIG. 8, the angle of inclination is set to an acute angle (that is, e is less than 90 degrees) to prevent the difference in angles between the bonding portions 100a and 100b and the wiring portion 100c from becoming excessively large.

As a result, the extending directions D2a and D2b of the bonding portions 100a and 100b are brought closer to the direction D1 in which the force acts, which reduces the forces that act to detach the bonding portions 100a and 100b from the conductive portions 61 and 62. As a result, the risk of the bonding portions 100a and 100b becoming detached from the conductive portions 61 and 62 due to the force may be reduced.

Note that FIG. 8 illustrates a case where the direction D1 in which a force acts due to thermal expansion of the sealing member 24 is perpendicular to the straight line (first line) L1 that joins the bonding portions 100a and 100b (passes through the bonding end 100a1 of the bonding portion 100a and the bonding end 100b1 of the bonding portion 100b). The present disclosure is not limited to this case, and when the direction DI of the force is not perpendicular to the straight line L1, it is sufficient to incline the extending directions D2a and D2b with respect to the directions D3a and D3b, respectively, toward the direction D1 of the force.

As one example, when the angle between the direction D1 and the direction D3a is less than 90 degrees and the extending direction D2a is matched to the direction D3a, a force will be applied to the bonding portion 100a from the wiring portion 100c side and will still act as a force in a direction that detaches the bonding portion 100a from the conductive portion 61. By inclining the extending direction D2a with respect to the direction D3a toward the direction D1, it is possible to prevent such a detaching force and reduce the risk of the bonding portion 100a becoming detached.

Next, a specific example of wire bonding in the power converter apparatus 10 will be described.

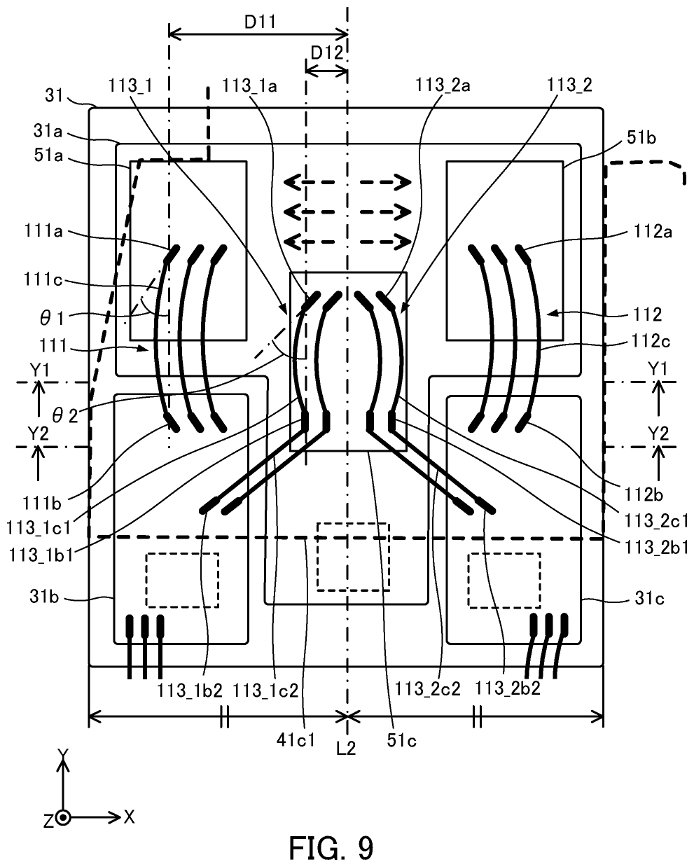

FIG. 9 is a first enlarged view of a part of a power converter apparatus according to the first embodiment. FIG. 9 depicts an enlargement of a peripheral region of the insulated circuit board 31 in FIG. 6.

In FIG. 9, the position of the horizontal portion 41c1 of the external connection terminal 41 depicted in FIGS. 4 and 5 is indicated by a broken line. As depicted in FIG. 9, the wires 111, 112, 113_1, and 113_2 are covered from above (the +Z direction) by the horizontal portion 41c1. With this configuration, below the horizontal portion 41c1, thermal expansion of the sealing member 24 in the upward (+Z) direction is restricted by the horizontal portion 41c1, which results in the sealing member 24 expanding in the horizontal direction.

Here, a straight line that passes through the center in the left-right direction (±X direction) of the horizontal portion 41c1 in FIG. 9 is defined as a “center line L2”. Below the horizontal portion 41c1 (in the −Z direction), the semiconductor chips 51a to 51c act as sources of heat. These semiconductor chips 51a to 51c are disposed with left-right symmetry with respect to the center line L2. In this case, the sealing member 24 expands in the left and right directions from the center line L2.

Each wire 111 includes a bonding portion 111a that is bonded to the output electrode of the semiconductor chip 51a, a bonding portion 111b that is bonded to the circuit pattern 31b, and a wiring portion 111c that connects the bonding portion 111a (bonding portion 111a at its one of opposite ends (joining end)) and the bonding portion 111b (bonding portion 111b at its one of opposite ends (joining end)). The direction that joins the bonding portion 111a and the bonding portion 111b is parallel to the center line L2. In this case, a force due to thermal expansion of the sealing member 24 acts on the bonding portions 111a and 111b from the center line L2 toward the left (the −X direction) in FIG. 9. For this reason, a direction from an end of the bonding portion 111a to a joining portion that connects to the wiring portion 111c is inclined at an acute angle with respect to the direction from the bonding portion 111a to the bonding portion 111b, toward the direction in which the force acts (which is leftward in FIG. 9). In FIG. 9, this angle (first acute angle) of inclination is expressed as “θ1”, where θ<θ1<90. By setting the angle in this way, it is possible to reduce the risk of the bonding portions 111a becoming detached from the semiconductor chip 51a due to the force described above.

For the bonding portions 111b also, a direction from an end of a bonding portion 111b to the joining portion that connects to the wiring portion 111c is inclined by an acute angle with respect to the direction from the bonding portion 111b to the bonding portion 111a, toward the direction of the force (the −X direction, which is leftward in FIG. 9). By setting the angle in this way, it is possible to reduce the risk of the bonding portions 111b becoming detached from the circuit pattern 31b due to the force described above.

Each wire 112 includes a bonding portion 112a that is bonded to the output electrode of the semiconductor chip 51b, a bonding portion 112b that is bonded to the circuit pattern 31c, and a wiring portion 112c that connects the bonding portions 112a and 112b. The direction that joins the bonding portion 112a and the bonding portion 112b is parallel to the center line L2. In this case, a force due to thermal expansion of the sealing member 24 acts on the bonding portions 112a and 112b from the center line L2 toward the right (the +X direction) in FIG. 9. For this reason, a direction from an end of the bonding portion 112a to a joining portion that connects to the wiring portion 112c is inclined at an acute angle with respect to the direction from the bonding portion 112a to the bonding portion 112b, toward the direction in which the force acts (which is rightward in FIG. 9). By setting the angle in this way, it is possible to reduce the risk of the bonding portions 112a becoming detached from the semiconductor chip 51b due to the force described above.

For the bonding portions 112b also, a direction from an end of a bonding portion 112b to the joining portion that connects to the wiring portion 112c is inclined by an acute angle with respect to a direction from the bonding portion 112b to the bonding portion 112a, toward the direction in which the force acts (which is rightward in FIG. 9). By setting the angle in this way, it is possible to reduce the risk of the bonding portions 112b becoming detached from the circuit pattern 31c due to the force described above.

The wires 113 include wires (second wire) 113_1 positioned on the left side (the −X direction) in FIG. 9 and wires 113_2 positioned on the right (the +X direction) in FIG. 9 with the center line L2 in between.

Each wire 113_1 includes a bonding portion (third bonding portion) 113_1a that is bonded to the output electrode of the semiconductor chip 51c and that has opposite ends (bonding end and joining end), a bonding portion (fourth bonding portion) 113_1b1 that is bonded to the output electrode of the semiconductor chip 51c and that has opposite ends (bonding end and joining end), a bonding portion 113_1b2 that is bonded to the circuit pattern 31b and that has opposite ends (bonding end and joining end), a wiring portion 113_1c1 that connects between the bonding portion 113_1a (bonding portion at one of its opposite ends (joining end)) and the bonding portion 113_1b1 (bonding portion at its one of opposite ends (joining end)), and a wiring portion 113_1c2 that connects between the joining end of the bonding portion 113_1b1 and joining end of the bonding portion 113_1b2. Thermal expansion of the sealing member 24 produces a force that acts on the wires 113_1 in the leftward direction (the −X direction) in FIG. 9.

A direction that joins the bonding portion 113_1a to the bonding portion 113_1b1 is parallel to the center line L2. For this reason, for each wire 113_1, the bonding direction of at least the bonding portion 113_1a is inclined. That is, the direction from an end of the bonding portion 113_1a to the joining portion that connects to the wiring portion 113_1c1 is inclined by an acute angle, with respect to a direction from the bonding portion 113_1a to the bonding portion 113_1b1, toward the direction of the force (the −X direction, which is leftward in FIG. 9). In FIG. 9, this angle (second acute angle) of inclination is expressed as “θ2”, where 0<θ2<90. By setting the angle in this way, it is possible to reduce the risk of the bonding portions 113_1a becoming detached from the semiconductor chip 51c due to the force described above.

Each wire 113_2 includes a bonding portion 113_2a that is bonded to the output electrode of the semiconductor chip 51c, a bonding portion 113_2b1 that is bonded to the output electrode of the semiconductor chip 51c, a bonding portion 113_2b2 that is bonded to the circuit pattern 31c, a wiring portion 113_2c1 that connects between the bonding portions 113_2a and 113_2b1, and a wiring portion 113_2c2 that connects between the bonding portions 113_2b1 and 113_2b2. Thermal expansion of the sealing member 24 produces a force that acts on the wires 113_2 in the rightward direction (the +X direction) in FIG. 9.

A direction that joins the bonding portion 113_2a to the bonding portion 113_2b1 is parallel to the center line L2. For this reason, for each wire 113_2, the bonding direction of at least the bonding portion 113_2a is inclined. That is, the direction from an end of the bonding portion 113_2a to the joining portion that connects to the wiring portion 113_2c1 is inclined by an acute angle, with respect to a direction from the bonding portion 113_2a to the bonding portion 113_2b1, toward the direction of the force (the +X direction, which is rightward in FIG. 9). By setting the angle in this way, it is possible to reduce the risk of the bonding portions 113_2a becoming the detached from semiconductor chip 51c due to the force described above.

Note that as another example, the direction from an end of the bonding portion 113_1b2 to the joining portion that connects to the wiring portion 113_1c2 may be inclined at an acute angle, with respect to a direction from the bonding portion 113_1b2 to the bonding portion 113 _1b1, toward the direction of the force (the −X direction, which is leftward in FIG. 9). Likewise, a direction from an end of the bonding portion 113_2b2 to the joining portion that connects to the wiring portion 113_2c2 may be inclined at an acute angle, with respect to a direction from the bonding portion 113_2b2 to the bonding portion 113_2b1, toward the direction of the force (rightward in FIG. 9 (the +X direction)).

In the left-right direction (the ±X direction) in FIG. 9, the force due to thermal expansion of the sealing member 24 increases toward the center line L2 (that is, upstream in the direction of the force). As one example, the distance D12 from the center line L2 to the wires 113_1 is shorter than the distance D11 from the center line L2 to the wires 111. This means that the force that acts upon the wires 113_1 is larger than the force that acts upon the wires 111. In this case, as one example, the angle of inclination θ2 of the bonding portions 113_1a of the wires 113_1 is set larger than the angle of inclination θ1 of the bonding portions 111a of the wires 111. With this configuration, detachment of the bonding portions 113_1a of the wires 113_1 may be more reliably prevented.

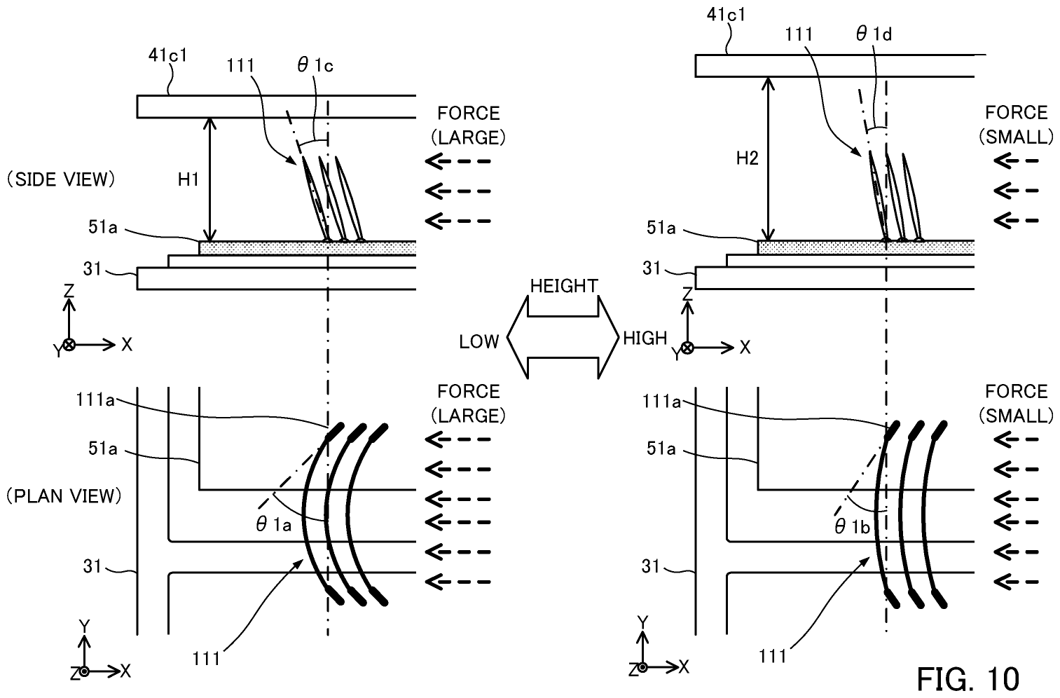

The magnitude of the force due to thermal expansion of the sealing member 24 also changes depending on the height of a covering member that covers the respective wires for example. This is described below with reference to FIG. 10.

FIG. 10 depicts how the force changes according to the height of the covering member, and the bonding directions of wires. The side views in the upper part of FIG. 10 depict a peripheral region of the wires 111 when looking from the direction of the chain line Y1-Y1 in FIG. 9. The plan views in the lower part of FIG. 10 are enlarged views of the peripheral region of the wires 111. Note that in FIG. 10, (the horizontal portion 41c1 included in) the external connection terminal 41 is given as an example of a covering member. The “covering member” may be any member that is sealed by the sealing member 24 and provided above the wires (in the +Z direction). The covering member is not limited to the external connection terminals 41 to 43, and as one example may be a beam (not illustrated) that is provided inside the case 22 and includes a facing surface. It is sufficient for the facing surface of the covering member to be disposed at a lower position (in the −Z direction) than the upper surface of the sealing member 24, and it is not needed for the entire covering member to be sealed within the sealing member 24.

The upper portions (in the +Z direction) of the wires 111 are covered by the horizontal portion 41c1 of the external connection terminal 41. Here, the lower the height of the horizontal portion 41c1, the more strongly expansion of the sealing member 24 in the upward direction (the +Z direction) is restricted, which tends to cause a corresponding increase in expansion in the horizontal direction so that the force in the horizontal direction increases.

On the left of FIG. 10, the height from the upper surface of the semiconductor chip 51a onto which the wires 111 are bonded to the lower surface of the horizontal portion 41c1 (that is, the facing surface that faces the insulated circuit board 31) is H1. The angle of inclination of the bonding portions 111a of the wires 100 is 01a. On the other hand, on the right side of FIG. 10, the height from the upper surface of the semiconductor chip 51a to the lower surface of the horizontal portion 41c1 is H2, where H2>H1. The angle of inclination of the bonding portion 111a of the wire 100 is θ1b.

For this example, the magnitude of the force generated in the leftward direction (the −X direction) in FIG. 9 is larger in the case depicted on the left side of FIG. 9 where the height is H1. For this reason, the angle of inclination θ1a of the bonding portions 111a of the wires 111 is set larger than the angle of inclination θ1b. By doing so, detachment of the bonding portions 111a of the wires 111 may be prevented more reliably.

As depicted in the upper part of FIG. 10, the erected direction (direction that is erect or “erect direction”) of the wires 111 may also be inclined toward the direction of the force due to thermal expansion of the sealing member 24. In the case depicted in FIG. 10, since the thermal expansion of the sealing member 24 applies a leftward force (the −X direction), the wires 111 are inclined to the left (in the −X direction) with respect to the vertically upward direction (the Z direction). By doing so, the force that acts so as to cause detachment of the bonding portions 111a and 111b is reduced.

It is desirable for the erected direction of the wires 111 to be more inclined as the force due to thermal expansion of the sealing member 24 increases. In FIG. 10, when the height of the covering member is H1, the angle of inclination of the erected direction of the wires 111 is θ1c, and when the height of the covering member is H2 (>H1), the angle of inclination of the erected direction of the wires 111 is θ1d. Since the force due to thermal expansion is greater when the height is H1 as described above, the angle of inclination of the erected direction of the wires 111 is set so that θ1c>θ1d. By doing so, the risk of the bonding portions 111a becoming detached may be reduced.

The greater the force due to thermal expansion of the sealing member 24, the greater the angle of inclination of the erected direction of the wires 111 and the angles of inclination of the bonding directions of the bonding portions 111a and 111b. By doing so, when looking from above, the wires 111 extend from the bonding portions 111a and 111b toward the centers of the wires 111 without being significantly bent. Bending of the wires 111 at the erected parts risks a reduction in the strength of such parts, but by inclining the erected direction of the wires 111 in keeping with the angle of inclination of the bonding directions of the bonding portions 111a and 111b as described above, such decrease in strength may be suppressed.

FIG. 11 is a second enlarged view of a part of the power converter apparatus according to the first embodiment. FIG. 11 is an enlargement of the peripheral region of the insulated circuit boards 33 and 34 in FIG. 6.

In FIG. 11, the position of the horizontal portion 43c of the external connection terminal 43 depicted in FIG. 5 is indicated by a broken line. As depicted in FIG. 11, the wires 132 and 141 are entirely covered and the wires 152, 153, 133, and 143 are partially covered from above (in the +Z direction) by the horizontal portion 43c. In this case, at locations below the horizontal portion 43c (in the −Z direction), upward expansion (in the +Z direction) of the sealing member 24 is restricted by the horizontal portion 43c, resulting in the sealing member 24 expanding in the horizontal direction.

Here, a straight line that passes through the center of the horizontal portion 43c in the left-right direction (the ±X direction) in FIG. 11 is defined as a “center line L3”. Below the horizontal portion 43c, the semiconductor chips 53b, 53c, 54a, and 54c act as heat sources. These semiconductor chips 53b, 53c, 54a, and 54c are disposed with left-right symmetry with respect to the center line L3. In this case, the sealing member 24 will expand in the left and right directions from the center line L3.

Each wire 132 includes a bonding portion 132a that is bonded to the circuit pattern 33b, a bonding portion 132b that is bonded to the output electrode of the semiconductor chip 53b, and a wiring portion 132c that connects the bonding portions 132a and 132b. A direction that joins the bonding portion 132a to the bonding portion 132b is parallel to the center line L3. In this case, a force due to thermal expansion of the sealing member 24 acts on the bonding portions 132a and 132b from the center line L3 in the leftward direction (the −X direction) in FIG. 9. For this reason, a direction from an end of each bonding portion 132a to the joining portion that connects to the wiring portion 132c is inclined at an acute angle with respect to a direction from the bonding portion 132a to the bonding portion 132b, toward the direction of the force (the leftward direction (the −X direction) in FIG. 9). By doing so, it is possible to reduce the risk of the bonding portions 132a becoming detached from the circuit pattern 33b due to this force.

For the bonding portions 132b also, the direction from the end of a bonding portion 132b to the joining portion that connects to the wiring portion 132c is inclined at an acute angle, with respect to a direction from the bonding portion 132b to the bonding portion 132a, toward the direction of the force (the leftward direction in FIG. 9). By doing so, it is possible to reduce the risk of the bonding portions 132b becoming detached from the semiconductor chip 53b due to the force described above.

On the other hand, the wires 141 are provided at a position that is opposite the wires 132 with the center line L3 in between. Each wire 141 includes a bonding portion 141a that is bonded to the circuit pattern 34b, a bonding portion 141b that is bonded to the output electrode of the semiconductor chip 54a, and a wiring portion 141c that connects the bonding portions 141a and 141b. A direction that joins the bonding portion 141a to the bonding portion 141b is parallel to the center line L3. In this case, a force due to thermal expansion of the sealing member 24 acts on the bonding portions 141a and 141b from the center line L3 in the rightward direction (the +X direction) in FIG. 11. For this reason, a direction from an end of each bonding portion 141a to a joining portion that connects to the wiring portion 141c is inclined at an acute angle, with respect to a direction from the bonding portion 141a to the bonding portion 141b, toward the direction of the force (the rightward direction (+X direction) in FIG. 11). By doing so, it is possible to reduce the risk of the bonding portions 141a becoming detached from the circuit pattern 34b due to the force described above.

For the bonding portions 141b also, a direction from an end of each bonding portion 141b to a joining portion that connects to the wiring portion 141c is inclined at an acute angle, with respect to a direction from the bonding portion 141b to the bonding portion 141a, toward the direction of the force (the rightward direction (the +X direction) in FIG. 11). By doing so, it is possible to reduce the risk of the bonding portions 141b becoming detached from the semiconductor chip 54a due to the force described above.

Each wire 152 includes a bonding portion 152a that is bonded to the circuit pattern 31c, a bonding portion 152b that is bonded to the circuit pattern 33a, and a wiring portion 152c that connects the bonding portions 152a and 152b. A direction that connects the bonding portion 152a to the bonding portion 152b is parallel to the center line L3. Out of the bonding portions 152a and 152b, only the bonding portions 152b are covered from above (in the +Z direction) by the horizontal portion 43c. In this case, a force due to thermal expansion of the sealing member 24 acts on the bonding portions 152b from the center line L3 toward the left (in the −X direction) in FIG. 11. For this reason, a direction from the end of a bonding portion 152b to the joining portion that connects to the wiring portion 152c is inclined at an acute angle, with respect to a direction from the bonding portion 152b to the bonding portion 152a, toward the direction of the force (the leftward direction in FIG. 11 (the −X direction)). By doing so, it is possible to reduce the risk of the bonding portions 152b becoming detached from the circuit pattern 33a due to the force described above.

On the other hand, the wires 153 are provided at a position that is opposite the wires 152 with the center line L3 in between. Each wire 153 includes a bonding portion 153a that is bonded to the circuit pattern 32b, a bonding portion 153b that is bonded to the circuit pattern 34a, and a wiring portion 153c that connects the bonding portions 153a and 153b. A direction that connects the bonding portion 153a to the bonding portion 153b is parallel to the center line L3. Out of the bonding portions 153a and 153b, only the bonding portion 153b are covered from above by the horizontal portion 43c. In this case, a force due to thermal expansion of the sealing member 24 acts on the bonding portions 153b from the center line L3 toward the right (the +X direction) in FIG. 11. For this reason, a direction from an end of a bonding portion 153b to a joining portion that connects to the wiring portion 153c is inclined at an acute angle, with respect to a direction from the bonding portion 153b to the bonding portion 153a, toward the direction of the force (the rightward direction in FIG. 11 (the +X direction). By setting the angle in this way, it is possible to reduce the risk of the bonding portions 153b becoming detached from the circuit pattern 34a due to the force described above.

Note that since the bonding portions 133a of the wires 133 are covered from above by the horizontal portion 43c, a force may act on the bonding portion 133a in the leftward direction (the −X direction) in FIG. 11. For this reason, the bonding directions of the bonding portions 133a may also be inclined. In the same way, since the bonding portions 143a of the wires 143 are covered from above (in the +Z direction) by the horizontal portion 43c, a force may act on the bonding portions 143a in the rightward direction (the +X direction) in FIG. 11. For this reason, the bonding direction of the bonding portions 143a may also be inclined.

Next, the force that acts on the wires 154 will be described. Each wire 154 includes a bonding portion 154a that is bonded to the circuit pattern 32c, a bonding portion 154b that is bonded to the circuit pattern 34a, and a wiring portion 154c that connects the bonding portions 154a and 154b. The wires 154 are provided near the fourth inner wall surface 23d of the side wall portion 23. A direction that joins the bonding portion 154a to the bonding portion 154b is parallel to the direction in which the fourth inner wall surface 23d extends (the vertical direction (the ±Y direction) in FIG. 11). Note that the wires 154 are covered from above by the protruding portion 23e (see FIGS. 1 and 6) that protrudes from the fourth inner wall surface 23d in the leftward direction (the −X direction) in FIG. 11.

When the sealing member 24 has expanded due to heat in this region in the vicinity of the fourth inner wall surface 23d, since expansion in the direction of the fourth inner wall surface 23d (that is, the +X direction) is restricted, the sealing member 24 expands in the opposite direction (that is, the −X direction) to the fourth inner wall surface 23d. For this reason, a force is generated in a direction from the fourth inner wall surface 23d toward the wires 154 (the leftward direction (−X direction) in FIG. 11). Since expansion of the region in the upward direction (Z direction) may be restricted by the protruding portion 23e and the lid portion 25 of the case 22, force is much more likely to be generated in the opposite direction to the fourth inner wall surface 23d. In particular, the lower the height of the protruding portion 23e, the greater the force.

For this reason, to prevent detachment of the wires 154, the bonding directions of the bonding portions 154a and 154b are inclined. In more detail, a direction from the end of a bonding portion 154a to the joining portion that connects to the wiring portion 154c is inclined at an acute angle, with respect to a direction from the bonding portion 154a to the bonding portion 154b, toward the direction of the force (the leftward direction (the −X direction) in FIG. 11). By doing so, it is possible to reduce the risk of the bonding portions 154a becoming detached from the circuit pattern 32c due to the force described above. Also, the direction from the end of each bonding portion 154b to the joining portion that connects to the wiring portion 154c is inclined by an acute angle, with respect to a direction from the bonding portion 154b to the bonding portion 154a, toward the direction of the force (the leftward direction (the −X direction) in FIG. 11). By doing so, it is possible to reduce the risk of the bonding portions 154b becoming detached from the circuit pattern 34a due to the force described above.

Also, the closer a position is to the fourth inner wall surface 23d, the greater the force due to thermal expansion of the sealing member 24 becomes. For this reason, the shorter the distances between the bonding portions 154a and 154b and the fourth inner wall surface 23d, the larger the inclination angles set for the directions in which the bonding portions 154a and 154b extend. By doing so, detachment of the bonding portions 154a and 154b of the wires 154 may be prevented more reliably.

In the first embodiment described above, the power converter apparatus 10 includes: an insulated circuit board 31 provided with conductive portions 61 and 62 on a front surface thereof; the wires 100 that connect the conductive portions 61 and 62; the case 22 including the housing region 22a that houses the insulated circuit board 31 and the wires 100; and the sealing member 24 that fills the housing region 22a and seals the insulated circuit board 31 and the wires 100. Each wire 100 includes the bonding portion 100a that is bonded to the conductive portion 61 and includes one end 100a1; the bonding portion 100b that is bonded to the conductive portion 62 and includes the other end 100b1; and the wiring portion 100c that spans between the conductive portions 61 and 62 to connect the joining portion 100a2 of the bonding portion 100a and the joining portion 100b2 of the bonding portion 100b that is opposite the joining portion 100a2, and is separated from the front surface of the insulated circuit board 31. The direction in which each bonding portion 100a extends from the one end 100a1 of each wire 100 to the joining portion 100a2 is inclined, when looking from above, at an acute angle with respect to the direction in which the bonding portion 100a is joined to the bonding portion 100b, toward the direction of a force that acts on the bonding portion 100a due to the thermal expansion of the sealing member 24. By doing so, it is possible to reduce the risk of the bonding portion 100a of each wire 100 becoming detached from the conductive portion 61 due to a force that accompanies thermal expansion of the sealing member 24.

The power converter apparatus 10 includes: the insulated circuit board 31 that has the semiconductor chip 51a and a circuit pattern 31b provided on the front surface; the wires 111 that connect the semiconductor chip 51a and the circuit pattern 31b, the case 22 which includes the housing region 22a for housing the insulated circuit board 31 and the wires 111; and the sealing member 24 that fills the housing region 22a and seals the insulated circuit board 31 and the wires 111. Each wire 111 includes a bonding portion 111a that is bonded to the semiconductor chip 51a and includes one (or “first”) end; a bonding portion 111b that is bonded to the circuit pattern 31b and includes another (or “second”) end; and a wiring portion 111c that spans between the semiconductor chip 51a and the circuit pattern 31b to connect the first joining end of the bonding portion 111a and a second joining end of the bonding portion 111b at the opposite end to the first joining point, and is separated from the front surface of the insulated circuit board 31. The power converter apparatus 10 also includes, at a position that is lower than the upper surface 24a of this filling sealing member 24, a horizontal portion 41c1 including a facing surface that faces the insulated circuit board 31 and covers the bonding portions 111a of the wires 111. A first extending direction in which the bonding portion 111a extends from a first end of a wire 111 to the first joining end is inclined, when looking from above, at an acute angle with respect to a center line L2 that is parallel to the first direction and passes through the center of the facing surface when looking from above toward a second direction that is perpendicular to the center line L2 and extends toward the bonding portion 111a. By doing so, the risk of the bonding portion 111a of the wire 111 becoming detached from the semiconductor chip 51a due to a force that accompanies thermal expansion of the sealing member 24 may be reduced.

### Second Embodiment

In the first embodiment described above, detachment of the bonding portions is prevented by inclining the directions in which the bonding portions extend from their ends, toward the direction of the force. On the other hand, it is also possible to prevent the bonding portions from becoming detached by inclining the erected directions of the wires toward the direction of the force.

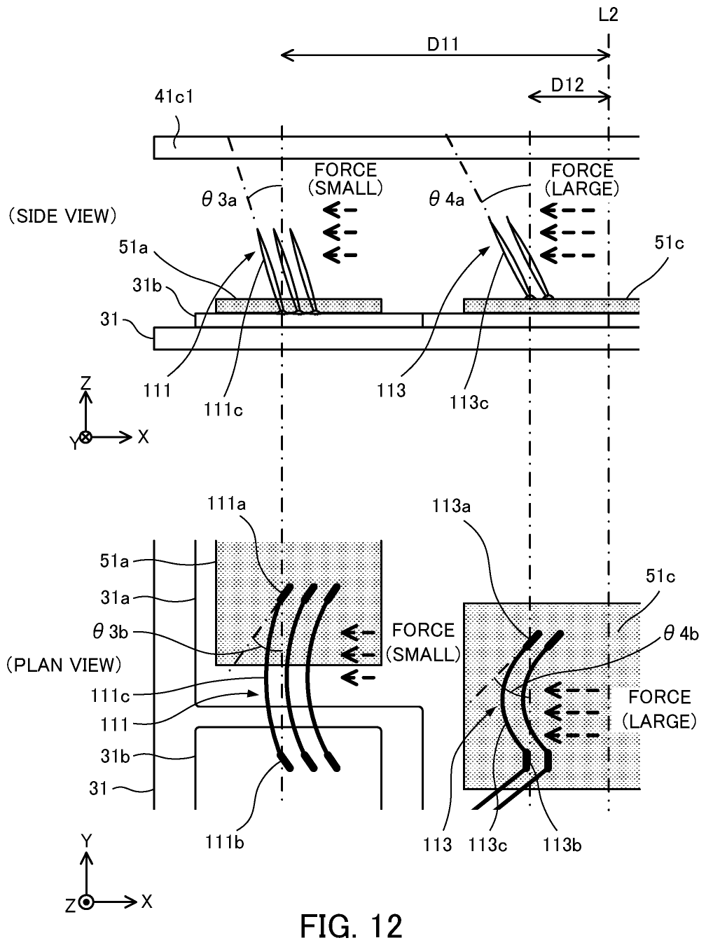

FIG. 12 depicts an erected state of wires in a power converter apparatus according to the second embodiment. The side view at the top of FIG. 12 depicts a peripheral region of the wires 111 and 113 in the power converter apparatus 10 as viewed from the direction of the chain line Y2-Y2 in FIG. 9. The plan view at the bottom of FIG. 12 is an enlarged view of the peripheral region of the wires.

As depicted in the side view in FIG. 12, when the sealing member 24 has expanded due to heat, a force acts on the wires 111 and 113 in a direction from the center line L2 of the horizontal portion 41c1 toward the wires 111 and 113 (the leftward direction in FIG. 12 (the −X direction)). In this configuration, the erected direction of the wiring portions 111c of the wires 111 are inclined with respect to a vertically upward direction (the +Z direction) toward the direction of the force. By doing so, it is possible to reduce the risk of the bonding portions 111a and 111b of the wires 111 becoming detached from the semiconductor chip 51a and the circuit pattern 31b due to the force described above. In the same way, the erected direction of the wiring portions 113c of the wires 113 is inclined with respect to the vertically upward direction (the +Z direction) toward the direction of the force. By doing so, it is possible to reduce the risk of the bonding portions 113a and 113b of the wires 113 becoming detached from the semiconductor chip 51c due to the force described above.

Also, as described earlier, the shorter the distance in the horizontal direction from the center line L2, the greater the force. In the example in FIG. 12, the distance D12 from the center line L2 to the wires 113 is shorter than the distance D11 from the center line L2 to the wires 111, which means that a larger force acts upon the wires 113. For this reason, the angle of inclination (second angle) θ4a of the wiring portions 113c of the wires 113 is set larger than the angle of inclination (first angle) θ3a of the wiring portions 111c of the wires 111.

Also, as depicted in FIG. 10, the lower the height from the insulated circuit board 31 to the lower surface of a covering member, such as the horizontal portion 41c, the greater the force. For this reason, the angles of inclination of the wires 111 and 113 are set larger, the lower the height of the horizontal portion 41c.

In addition, as depicted in FIG. 11, when a wire is present in the periphery of the side surface of a member that is erected vertically (in FIG. 11, the fourth inner wall surface 23d of the side wall portion 23), expansion of the sealing member 24 due to heat causes a force to act on the wire in the opposite direction (the −X direction) to the side surface. For this reason, the erected direction of the wire is inclined in the direction of the force (that is, in the opposite direction to the side surface when looking from the wire). By doing so, it is possible to reduce the risk of the bonding portion of the wire becoming detached from the bonded surface due to the force. As the distance between a wire and the side surface decreases, the greater the force that acts on the wire, and therefore the larger the angle of inclination set for the wire.

In the second embodiment described above, the power converter apparatus 10 includes: the insulated circuit board 31 provided with the semiconductor chip 51a and the circuit pattern 31b on the front surface; the wires 111 that connect the semiconductor chip 51a and the circuit pattern 31b; the case 22 that includes the housing region 22a for housing the insulated circuit board 31 and the wires 111; and the sealing member 24 that fills the housing region 22a and seals the insulated circuit board 31 and the wires 111. Each wire 111 includes the bonding portion 111a that is bonded to the semiconductor chip 51a and includes one (or “first”) end; the bonding portion 111b that is bonded to the circuit pattern 31b and includes another (or “second”) end; and the wiring portion s between the semiconductor chip 51a and the circuit pattern 31b to connect the bonding portion 111a and the bonding portion 111b and is separated from the front surface of the insulated circuit board 31. The direction in which the wiring portion 111c is erected from the front surface of the insulated circuit board 31 is inclined, when looking from above, with respect to a direction perpendicular to the front surface, toward the direction of a force that acts on the wire 111 due to expansion of the sealing member 24. By doing so, it is possible to reduce the risk of the bonding portions 111a and 111b of the wires 111 becoming detached from the semiconductor chip 51a and the circuit pattern 31b due to a force that accompanies thermal expansion of the sealing member 24.

Note that the method of inclining the extending direction of the bonding portions of the wires in the first embodiment and the method of inclining the erected direction of the wires in the second embodiment may be used together. For the example in FIG. 12, as depicted in the plan view at the bottom of FIG. 12, the bonding portions 111a of the wires 111 and the bonding portions 113a of the wires 113 are inclined. In more detail, a direction from an end of the bonding portion 111a to the joining portion that connects to the wiring portion 111c is inclined, with respect to a direction from the bonding portion 111a to the bonding portion 111b, by an angle of inclination 03b toward the direction of a force due to thermal expansion (toward the left in FIG. 12 (the −X direction)). A direction from an end of the bonding portion 113a to the joining portion that connects to the wiring portion 113c is inclined with respect to a direction from the bonding portion 113a to the bonding portion 113b by an angle of inclination 04b toward the direction of the force due to thermal expansion (toward the left in FIG. 12 (the −X direction)). By doing so, it is possible to reduce the risk of the bonding portions 111a and 113a becoming detached from the semiconductor chips 51a and 51c due to a force caused by thermal expansion.

Also, as described earlier, the shorter the distance in the horizontal direction from the center line L2 of the horizontal portion 41c1, the greater the force due to thermal expansion. In the example in FIG. 12, since the distance D12 from the center line L2 to the wires 113 is shorter than the distance D11 from the center line L2 to the wires 111, a larger force acts on the wires 113. For this reason, the angle of inclination 04b of the bonding portions 113a of the wires 113 is set larger than the angle of inclination 03b of the bonding portions 111a of the wires 111.

According to the present disclosure, the risk of wires becoming detached by a force that accompanies thermal expansion of a sealing member is reduced.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A power converter apparatus, comprising:
a substrate including a first conductive portion and a second conductive portion provided on a front surface thereof;
a first wire that is connected to the first conductive portion and to the second conductive portion and includes:
first and second bonding portions that are bonded respectively to the first and second conductive portions and each have at opposite ends thereof respectively a bonding end and a joining end; and
a wiring portion having opposite ends, one of the opposite ends of the wiring portion being connected to the joining end of the first bonding portion and the other of the opposite ends of the wiring portion being connected to the joining end of the second bonding portion, the wiring portion being located away from the front surface of the substrate;
a case including a housing region that houses the substrate and the first wire; and
a sealing member that fills the housing region and seals the substrate and the first wire, wherein
in a plan view of the power converter apparatus, a first extending direction in which the first bonding portion of the first wire extends from the bonding end of the first bonding portion to the first joining end of the first bonding portion is inclined at a first acute angle, from a first direction of a first line passing through the bonding ends of first and second bonding portions, toward a second direction of a force that acts on the first bonding portion due to thermal expansion of the sealing member.

2. The power converter apparatus according to claim 1, wherein
the substrate further includes a third conductive portion and a fourth conductive portion provided on the front surface thereof,
the power converter apparatus further comprises a second wire that is connected to the third conductive portion and to the fourth conductive portion, is sealed by the sealing member, and includes:
first and second bonding portions that are bonded respectively to the third and fourth conductive portions and each have at respective opposite ends thereof a bonding end and a joining end; and
a wiring portion having opposite ends, one of the opposite ends of the wiring portion of the second wire being connected to the joining end of the first bonding portion of the second wire and the other of the opposite ends of the wiring portion of the second wire being connected to the joining end of the second bonding portion of the second wire, the wiring portion of the second wire being located away from the front surface of the substrate,
the force in the second direction also acts on the first bonding portion of the second wire, a direction of a line that passes through the joining ends of the first and second bonding portions of the second wire is parallel to the first line, and in the plan view, a second extending direction in which the first bonding portion of the second wire extends from the bonding end of the first bonding portion of the second wire to the joining end of the first bonding portion of the second wire is inclined at a second acute angle, from the first direction, toward the second direction.

3. The power converter apparatus according to claim 2, wherein the first bonding portion of the second wire is disposed at an upstream side with respect to the second direction of the force, and the second acute angle of the second extending direction inclined from the first direction is larger than the first acute angle of the first extending direction inclined from the first direction.

4. The power converter apparatus according to claim 2, further comprising a covering member including, at a position that is lower than an upper surface of the sealing member, a facing surface that faces the substrate and covers the first bonding portion of the first wire and the first bonding portion of the second wire, wherein
in the plan view, the first bonding portion of the second wire is disposed closer to a center line, which is parallel to the first line and passes through a center of the facing surface, than is the first bonding portion of the first wire, and
the second acute angle of the second extending direction inclined from the first direction is larger than the first acute angle of the first extending direction inclined from the first direction.

5. The power converter apparatus according to claim 1,
further comprising a covering member including, at a position that is lower than an upper surface of the sealing member, a facing surface that faces the substrate and covers the first bonding portion of the first wire, wherein
in the plan view, the first acute angle of the first extending direction inclined from the first direction increases as a distance between the first bonding portion of the first wire and a center line decreases, the center line being parallel to the first line and passing through a center of the facing surface.

6. The power converter apparatus according to claim 5, wherein the first acute angle increases as a height from the front surface of the substrate to the facing surface decreases.

7. The power converter apparatus according to claim 1,
further comprising a semiconductor chip including a main electrode on a front surface thereof, wherein
the substrate includes an insulating plate and a plurality of circuit patterns including a first circuit pattern which is provided on a front surface of the insulating plate and on which the semiconductor chip is bonded,
the first conductive portion is the main electrode or one out of the plurality of circuit patterns aside from the first circuit pattern, and
the second conductive portion is the main electrode or one out of the plurality of circuit patterns aside from the first circuit pattern.

8. The power converter apparatus according to claim 1, wherein a diameter of the first wire is in a range of 300 μm to 500 μm.

9. A power converter apparatus, comprising:
a substrate including a first conductive portion and a second conductive portion provided on a front surface thereof;
a first wire that is connected to the first conductive portion and to the second conductive portion and includes:
first and second bonding portions that are bonded respectively to the first and second conductive portions and each have at opposite ends thereof respectively a bonding end and a joining end; and
a wiring portion having opposite ends, one of the opposite ends of the wiring portion being connected to the joining end of the first bonding portion and the other of the opposite ends of the wiring portion being connected to the joining end of the second bonding portion, the wiring portion being located away from the front surface of the substrate;
a case including a housing region that houses the substrate and the first wire;
a sealing member that fills the housing region and seals the substrate and the first wire; and
a covering member that includes, at a position that is lower than an upper surface of the sealing member, a facing surface that faces the substrate and covers the first bonding portion, wherein
in a plan view of the power converter apparatus, a first extending direction in which the first bonding portion extends from the bonding end of the first bonding portion to the joining end of the first bonding portion is inclined at a first acute angle, from a first direction of a first line passing through the bonding ends of the first and second bonding portions toward a second direction is that perpendicular to a center line that is parallel to the first line and passes through a center of the facing surface.

10. The power converter apparatus according to claim 9,
wherein the substrate further includes a third conductive portion and a fourth conductive portion provided on the front surface thereof,
the power converter apparatus further comprises a second wire that is connected to the third conductive portion and to the fourth conductive portion, is sealed by the sealing member, and includes:
first and second bonding portions that are bonded respectively to the third and fourth conductive portions and each have at respective opposite ends thereof a bonding end and a joining end; and
a wiring portion having opposite ends, one of the opposite ends of the wiring portion of the second wire being connected to the joining end of the first bonding portion of the second wire and the other of the opposite ends of the wiring portion of the second wire being connected to the joining end of the second bonding portion of the second wire, the wiring portion of the second wire being located away from the front surface of the substrate,
the first bonding portion of the second wire is covered by the facing surface of the covering member,
a direction of a line that passes through the joining ends of the first and second bonding portions of the second wire is parallel to the first line,
the first bonding portion of the second wire is disposed closer to the center line than is the first bonding portion of the first wire, and
a second extending direction in which the first bonding portion of the second wire extends from the bonding end of the first bonding portion of the second wire to the joining end of the first bonding portion of the second wire is inclined at a second acute angle from the first direction, toward the second direction, the second acute angle being larger than the first acute angle.

11. The power converter apparatus according to claim 9, wherein the first acute angle of the first extending direction inclined from the first direction increases as a height from the front surface of the substrate to the facing surface decreases.

12. A power converter apparatus, comprising:
a substrate including a first conductive portion and a second conductive portion provided on a front surface thereof;
a first wire that is connected to the first conductive portion and to the second conductive portion and includes:
first and second bonding portions that are bonded respectively to the first and second conductive portions and each have at opposite ends thereof respectively a bonding end and a joining end; and
a wiring portion having opposite ends, one of the opposite ends of the wiring portion being connected to the joining end of the first bonding portion and the other of the opposite ends of the wiring portion being connected to the joining end of the second bonding portion, the wiring portion being located away from the front surface of the substrate;
a case including a housing region that houses the substrate and the first wire; and
a sealing member that fills the housing region and seals the substrate and the first wire, wherein
in a side view of the power converter apparatus, a first erect direction in which the wiring portion is erected on the front surface of the substrate is inclined at a first angle, from a first direction that is perpendicular to the front surface, toward a second direction of a force that acts on the first wire due to thermal expansion of the sealing member.

13. The power converter apparatus according to claim 12, wherein
the substrate further includes a third conductive portion and a fourth conductive portion provided on the front surface thereof,
the power converter apparatus further comprises a second wire that is connected to the third conductive portion and to the fourth conductive portion, is sealed by the sealing member, and includes:
first and second bonding portions that are bonded respectively to the third and fourth conductive portions and each have at respective opposite ends thereof a bonding end and a joining end; and
a wiring portion having opposite ends, one of the opposite ends of the wiring portion of the second wire being connected to the joining end of the first bonding portion of the second wire and the other of the opposite ends of the wiring portion of the second wire being connected to the joining end of the bonding portion of the second wire, the wiring portion of the second wire being located away from the front surface of the substrate, wherein
the force in the second direction also acts on the first bonding portion of the second wire,
a third direction of a third line passing through the bonding ends of the first and second bonding portions of the first wire is parallel to a fourth direction of a fourth line passing through the joining ends of the first and second bonding portions of the second wire, and
in the side view, a second erect direction in which the wiring portion of the second wire is erected on the front surface of the substrate is inclined at a second angle from the first direction toward the second direction.

14. The power converter apparatus according to claim 13, wherein
the second wire is disposed at an upstream side with respect to the second direction of the force, and
in the side view, the second angle of the second erect direction inclined from the first direction is larger than the first angle the first erect direction inclined from the first direction.

15. The power converter apparatus according to claim 13,
further comprising a covering member including, at a position that is lower than an upper surface of the sealing member, a facing surface that faces the substrate and covers the first wire and the second wire, wherein
in the plan view, the second wire is disposed closer to a center line, which is parallel to the third line and passes through a center of the facing surface, than is the first wire, and
the second angle of the second erect direction inclined from the first direction is larger than the first angle of the first erect direction inclined from the first direction.

16. The power converter apparatus according to claim 12,
further comprising a covering member including, at a position that is lower than an upper surface of the sealing member, a facing surface that faces the substrate and covers the first wire, wherein
in the side view, the first angle of the first erect direction inclined from the first direction increases as a distance on the substrate between the first wire and a center line decreases, the center line being parallel to a third direction of a third line that passes through the first and second bonding ends of the first and second bonding portions of the first wire passing through a center of the facing surface.

17. The power converter apparatus according to claim 16, wherein the first angle of the first erect direction inclined from the first direction increases as a height from the front surface of the substrate to the facing surface decreases.
